(19) United States
(12) Patent Application Publication
(10) Pub. No.: US 2026/0314443 A1
(43) Pub. Date: Oct. 8, 2026

(54) SYSTEM-IN-PACKAGE (SIP) CONFIGURED TO RECEIVE MULTIPLE MEMORY DIES

(71) Applicant: QUALCOMM Incorporated, San Diego, CA (US)

(72) Inventors: Ryan LANE, San Diego, CA (US); Charles David PAYNTER, Encinitas, CA (US); Li-Sheng WENG, San Diego, CA (US); John HOLMES, Escondido, CA (US); Feng ZHU, San Diego, CA (US); Akshay BILAGI, San Diego, CA (US)

(21) Appl. No.: 19/640,160

(22) Filed: Apr. 6, 2026

Related U.S. Application Data
(60) Provisional application No. 63/784,580, filed on Apr. 7, 2025.

(51) Int. Cl. H10W 70/60; H10B 80/00; H10D 80/30; H10W 70/652; H10W 70/655; H10W 74/01; H10W 74/15; H10W 76/01; H10W 76/40; H10W 90/00; H10W 90/10

(52) U.S. Cl. CPC H10W 70/614; H10W 70/652; H10W 70/655; H10W 74/012; H10W 76/01; H10W 76/40; H10W 90/10; H10W 90/724; H10B 80/00; H10D 80/30; H10W 74/15

(57) ABSTRACT

A package includes one or more dies that include one or more processors and a substrate that defines multiple empty memory attach regions. The substrate includes a first set of contacts electrically coupled to the one or more dies and multiple second sets of contacts within the multiple empty memory attach regions. At least a portion of each of the multiple second sets of contacts is exposed along an upper surface of the substrate. The multiple second sets of contacts are configured to be electrically coupled to multiple memory dies. The substrate also includes one or more conductors that electrically couple the first set of contacts to the multiple second sets of contacts.

### CROSS-REFERENCE TO RELATED APPLICATIONS

The present application claims priority from the commonly owned U.S. Provisional Patent Application No. 63/784,580, filed Apr. 7, 2025, entitled “SYSTEM-IN-PACKAGE (SIP) CONFIGURED TO RECEIVE MULTIPLE MEMORY DIES”, the content of which is incorporated herein by reference in its entirety.

### FIELD

Various features relate to a system-in-package (SiP) configured to receive multiple memory dies.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

In state-of-the-art electronic devices, there is generally an expectation that integrated device packages have a small form factor, a low cost, a tight power budget, and high performance. These various goals are often in conflict. For example, supporting high performance and increasingly complex functionality can often include adding multiple components to the same integrated device package. As an example, a system-in-package (SiP) that includes one or more processor dies also typically includes one or more memory dies to support various functionality. Each die that is included in the same SiP increases the size of the form factor. Some SiP manufacturers design the SiP to include a fixed number of memory dies having particular characteristics, such as storage capacity, operating characteristics, or the like, that are expected to provide a balance between the goals of high performance and small form factor. However, different users of the SiP may plan to use the SiP in different devices or situations, and such a one-size-fits-all approach can reduce flexibility, and thus utility, of the SiP for some users.

### SUMMARY

Various features relate to integrated device packages.

One example provides a package that includes one or more dies that include one or more processors and a substrate that defines multiple empty memory attach regions. The substrate includes a first set of contacts electrically coupled to the one or more dies and multiple second sets of contacts within the multiple empty memory attach regions. At least a portion of each of the multiple second sets of contacts is exposed along an upper surface of the substrate. The multiple second sets of contacts are configured to be electrically coupled to multiple memory dies. The substrate also includes one or more conductors that electrically couple the first set of contacts to the multiple second sets of contacts.

Another example provides a package that includes a substrate. The substrate includes a first set of contacts, multiple second sets of contacts, and one or more conductors that electrically couple the first set of contacts to the multiple second sets of contacts. The package includes one or more dies electrically coupled to the first set of contacts. The one or more dies include one or more processors. The package also includes multiple memory dies electrically coupled to the multiple second sets of contacts. An underfill material is disposed between the one or more dies and the substrate and not between the multiple memory dies and the substrate.

Another example provides a method of fabrication that includes providing a substrate that defines multiple empty memory attach regions. The substrate includes a first set of contacts and multiple second sets of contacts within the multiple empty memory attach regions. At least a portion of each of the multiple second sets of contacts is exposed along an upper surface of the substrate. The multiple second sets of contacts are configured to be electrically coupled to multiple memory dies. The substrate also includes one or more conductors that electrically couple the first set of contacts to the multiple second sets of contacts. The method also includes electrically coupling one or more dies to the first set of contacts. The one or more dies include one or more processors. The method also includes depositing an underfill material between the one or more dies and the substrate.

Optional additional aspects are described in the dependent claims.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a cross-sectional profile view of an example of a package that includes one or more processors and a stiffener structure and that is configured to receive multiple memory dies.

FIG. 1B illustrates a top view of the package of FIG. 1A.

FIG. 1C illustrates a top view of another example of a package that includes one or more processors and a stiffener structure and that is configured to receive multiple memory dies.

FIG. 1D illustrates a top view of another example of a package that includes one or more processors and a stiffener structure and that is configured to receive multiple memory dies.

FIG. 1E illustrates a top view of another example of a package that includes one or more processors and a stiffener structure and that is configured to receive multiple memory dies.

FIG. 1F illustrates a cross-sectional profile view of an example of a package that includes one or more processors and that is configured to receive multiple memory dies.

FIG. 1G illustrates a top view of the package of FIG. 1F.

FIG. 1H illustrates a top view of an example of a package that includes one or more processors and a lid structure and that is configured to receive multiple memory dies.

FIG. 2A illustrates a cross-sectional profile view of an example of a package that includes one or more processor dies and multiple later-attached memory dies.

FIG. 2B illustrates a top view of the package of FIG. 2A.

FIG. 3A illustrates a first part of an exemplary sequence for fabricating an exemplary package that includes one or more processor dies and that is configured to receive multiple memory dies.

FIG. 3B illustrates a second part of an exemplary sequence for fabricating an exemplary package that includes one or more processor dies and that is configured to receive multiple memory dies.

FIG. 4 illustrates an exemplary flow diagram of a method of fabrication for a package that includes one or more processor dies and that is configured to receive multiple memory dies.

FIG. 5 illustrates various electronic devices that may integrate an exemplary package that includes one or more processor dies and that is configured to receive multiple memory dies described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, components and circuitry may be shown in block diagrams in order to avoid obscuring the aspects in unnecessary detail. In other instances, well-known structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

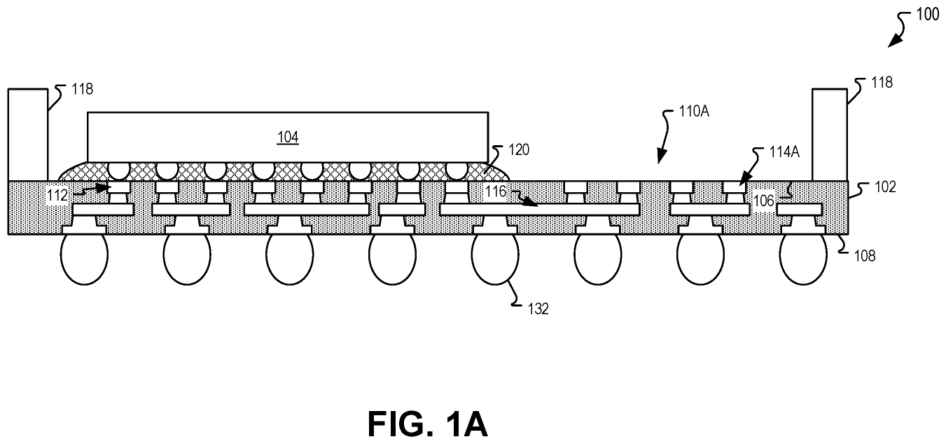

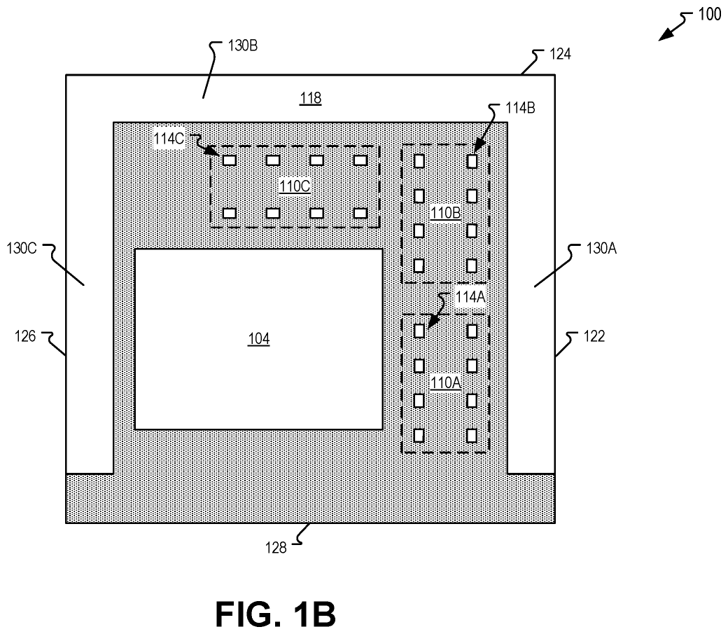

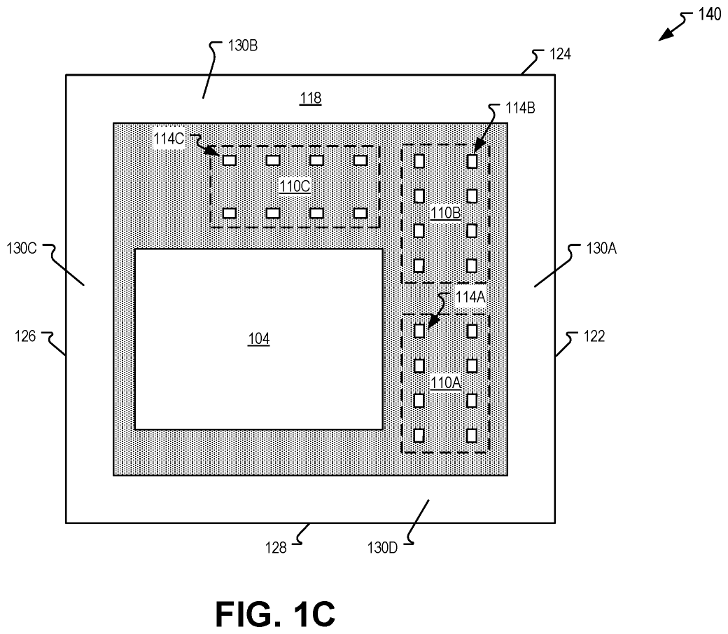

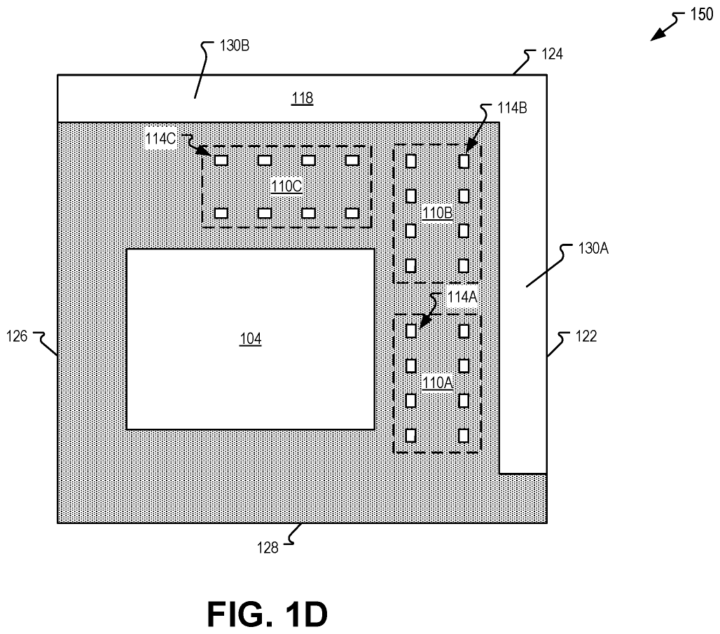

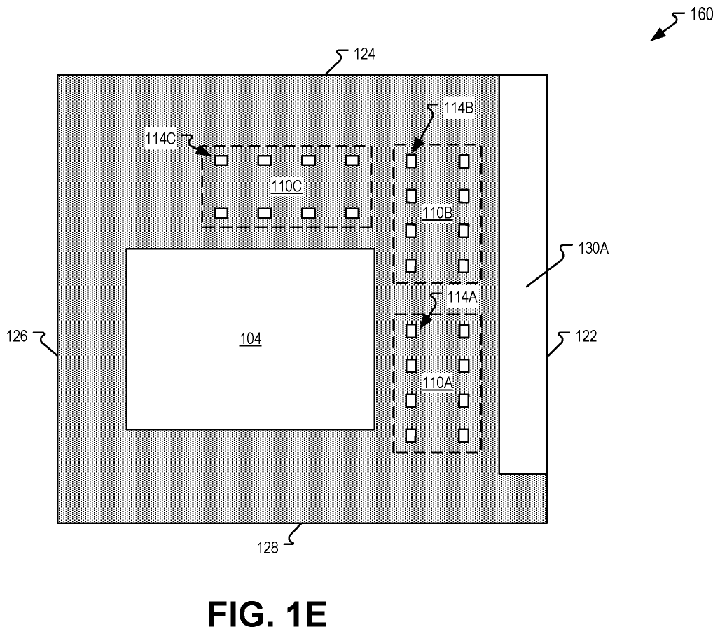

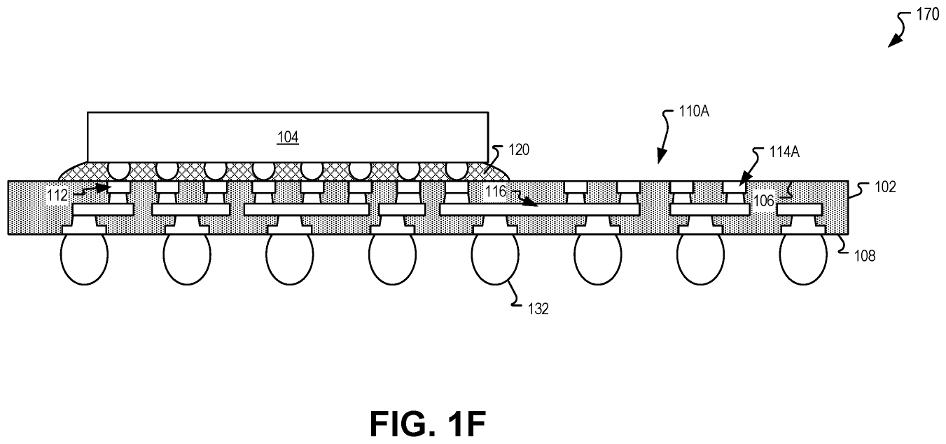

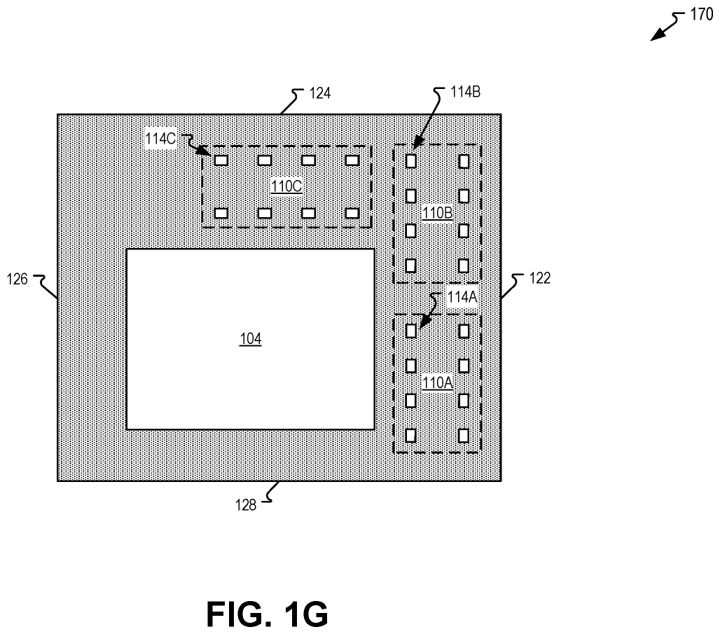

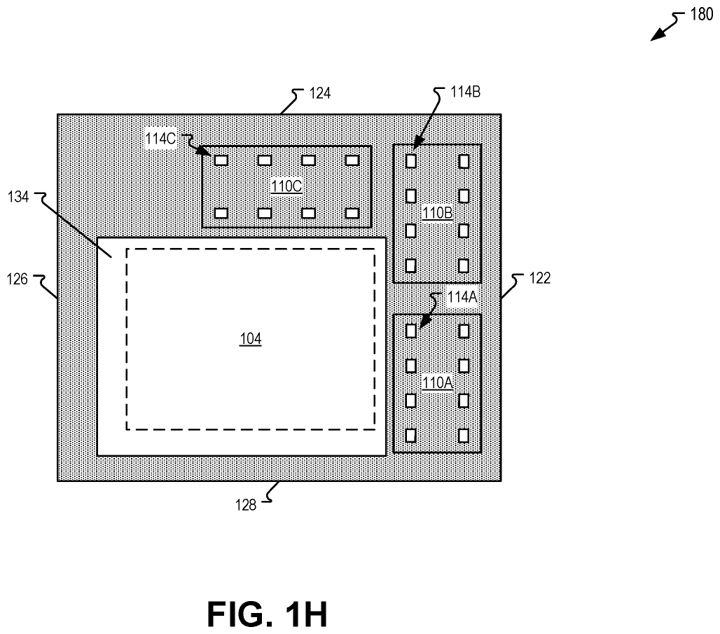

In some drawings in which multiple instances of a particular type of feature are used, different instances are distinguished by addition of a letter to the reference number. In this case, when the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1B, multiple memory attach regions are illustrated and associated with reference numbers 110A, 110B, and 110C. When referring to a particular one of these memory attach regions, such as a memory attach region 110A, the distinguishing letter “A” is used. However, when referring to any arbitrary one of these memory attach regions or to these memory attach regions as a group, the reference number 110 is used without a distinguishing letter.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art device.

These interconnections include back-end-of-line (BEOL) interconnect layers, which may refer to the conductive interconnect layers for electrically coupling to front end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies within a single package. One example of a multi-die package is a two-dimensional (2D) package architecture, in which two or more dies are coupled to a package substrate side-by-side with one another. Dies in this configuration can interact with one another (e.g., via die-to-die connections) and with off-package devices (e.g., via off-package connections). A challenge of such configurations is that die-to-die and off-package connections have different design criteria. For example, off-package connections are generally larger (e.g., in terms of line width, line spacing, etc.) than is needed for die-to-die connections. Various workarounds have been used to address this size difference. For example, additional devices (e.g., interposer devices or bridge die) can be added to a package to route die-to-die connections using smaller lines. As another example, additional layers or a separate stacked substrate can be added to the package substrate to provide die-to-die connection and redistribution routing to connect to off-package connections.

Another approach to reducing package size is a 2.5D architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. As used herein, a side-by-side configuration or side-by-side arrangement refers to multiple dies or chiplets that are disposed adjacent to one another (typically in a horizontal direction) on the same substrate or interposer (or interconnected substrates or interposers) instead of being stacked vertically as a three-dimensional (3D) IC device. A 3D IC device refers to an IC device that stacks multiple layers of chips or chiplets on top of each other. Stacked die schemes and chiplet architectures are becoming more common as significant power performance area (PPA) yield enhancements are demonstrated for stacked die and chiplet architecture product lines.

Aspects of the present disclosure are directed to a package (e.g., an integrated device package) that includes one or more processors, such as a system-on-chip (SOC), and that is configured to receive multiple memory dies. The memory dies may be attached to sets of contacts that are configured to electrically couple the memory dies to the processor(s) in a side-by-side arrangement at a later time, such as after fabrication and shipment of the package to a user or customer. In some aspects, the package includes a die that includes one or more processors and a substrate that defines multiple empty memory attach regions. An underfill material may be disposed between the die and the substrate, but the underfill material is omitted from the empty memory attach regions to enable later attachment of memory dies in the empty memory attach regions. In some aspects, the substrate includes a first set of contacts that are electrically coupled to the die, as well as multiple second sets of contacts within the multiple empty memory regions. The multiple second sets of contacts may be disposed on, or at least partially embedded within, the substrate such that at least a portion of each of the multiple second sets of contacts is exposed along an upper surface of the substrate. The substrate also includes one or more connectors, such as traces or vias within the substrate, that electrically couple the first set of contacts to the multiple second sets of contacts. Each set of the second sets of contacts is configured to be electrically coupled to a respective memory die, such that various memory dies can be attached to the package at a later time to form a system in package (SiP) based on criteria that are specific to a user. In some implementations, a stiffener structure is coupled to the substrate and configured to resist warpage of the substrate based on mechanical properties of the memory dies to be attached in the empty memory attachment regions.

The disclosed package that includes the one or more processors and that is configured to receive multiple memory dies provides a more flexible SiP that can be individually designed, through the selection of particular memory dies to be attached, than other SiPs that are manufactured and sold with memory dies already attached. For example, because the multiple second sets of contacts can be configured to receive various types of memory dies, such as memory dies by different manufacturers or that have different storage capacities, a user of the disclosed SiP can select memory dies to attach to the SiP to match particular operating criteria, instead of being limited by the operating characteristics of pre-attached memory dies. Additionally, the location of the memory attach regions may be designed to be close to the processor die(s) to improve signal quality between the processor die(s) and the memory die(s) as well as to reduce the overall form factor size of the SiP, as compared to other SiPs that come with pre-installed memory dies and underfill material underneath the memory dies, as well as compared to memory dies that include a large number of memory dies to support target operating criteria which may be more stringent than desired for many users, which reduces cost and complexity of fabricating the SiP. In implementations that include the stiffener structure, the stiffener structure may help reduce warpage of the substrate during the process of attaching the memory dies, due to the presence of the memory dies at a later time, or both, which can decrease a likelihood of damage to the SiP during the process of attaching the memory dies or which can increase the operational lifespan of the SiP.

### Exemplary Packages Including Processor Die(s) and Configured to Receive Multiple Memory Dies

FIGS. 1A-H illustrate examples of various packages that include processor die(s) and that are configured to receive multiple memory dies, such as to form respective SiPs. FIG. 1A illustrates a cross-sectional profile view of a package 100 that includes one or processors and a stiffener structure that is configured to receive multiple memory dies, and FIG. 1B illustrates a top view of the package 100 of FIG. 1A. FIG. 1C illustrates a top view of a package 140 that is similar to the package 100 except for aspects of the stiffener structure. FIG. 1D illustrates a top view of a package 150 that is similar to the package 100 except for aspects of the stiffener structure. FIG. 1E illustrates a top view of a package 160 that is similar to the package 100 and the package 150 except for aspects of the stiffener structure. FIG. 1F illustrates a cross-sectional profile view of a package 170 that includes one or processors and that is configured to receive multiple memory dies (and omits a stiffener structure), and FIG. 1G illustrates a top view of the package 170 of FIG. 1A. FIG. 1H illustrates a top view of a package 180 that includes one or more processors and a lid structure and that is configured to receive multiple memory dies.

As shown in FIGS. 1A-B, the package 100 includes a substrate 102, one or more dies 104 (referred to herein collectively as “the die 104”) electrically coupled to the substrate 102, and a stiffener structure 118 coupled to the substrate 102. The substrate 102 defines multiple empty memory attach regions 110, as further described below. The substrate 102 (e.g., a package substrate) includes one or more metal layers that are separated from one another by one or more dielectric layers and that are patterned and interconnected to form various contacts and conductors. For example, the substrate 102 may include metal layers interspersed with dielectric layers between a first surface 106 (e.g., a top surface) and a second surface 108 (e.g., a bottom surface). The substrate 102, or portions thereof, can be formed using different materials or techniques that contribute to various characteristics of the substrate 102, such as a thickness, a count of layers, layer thicknesses, or a combination thereof. As one illustrative example, the substrate 102 can be formed using lamination techniques and may include a metal-prepreg composite stack, in which the dielectric layers include fiber-reinforced polymer layers. Alternatively, the substrate 102 can include a set of redistribution layers, in which the dielectric layers include unreinforced polymer layers. In the example in which the substrate 102 (or a top portion thereof) includes the set of redistribution layers, metal layers included in the redistribution layers are each thinner than in the example in which lamination techniques are used to form the substrate 102, as is typical for redistribution layers as compared to laminated metal-prepreg composite stacks.

In the example shown in FIGS. 1A-B, the substrate 102 includes contacts 112 (e.g., a first set of contacts), contacts 114 (e.g., multiple second sets of contacts), and one or more conductors 116 (referred to herein collectively as “the conductors 116”). The contacts 112 are located on, or at least partially embedded within, the substrate 102 and electrically coupled to the die 104. For example, the contacts 112 may include metal pads or traces that are disposed on the first surface 106, or at least partially embedded within the substrate 102 (e.g., the substrate 102 may be an embedded trace substrate (ETS)), such that at least a portion of each of the contacts 112 are exposed for coupling to the die 104. The exposed portions of the contacts 112 may be physically and electrically coupled to die contacts or die interconnects on the bottom of the die 104, such as microbumps, conductive pillars, conductive pads (e.g., for pad to pad bonding), solder balls, metal balls, or any other type of conductive structures that electrically couple circuitry of the die 104 to the contacts 112.

The contacts 114 are located within the memory attach regions 110. For example, each of the memory attach regions 110 may include (e.g., have located within) a respective set of the contacts 114. Each of the sets of the contacts 114 are configured to be electrically coupled to a respective memory die at a later time (e.g., after fabrication and selling/shipment to a user or customer), such that the contacts 114 cause the package 100 to be configured to be electrically coupled to multiple memory dies. For example, at least a portion of each of the contacts 114 is exposed along the first surface 106 of the substrate 102 such that the customer or user may later attach their choice of memory dies to the contacts 114, which improves flexibility and reduces cost of the package 100. In some implementations, the contacts 114 are disposed and exposed on the first surface 106 in the memory attach regions 110. In some other implementations, at least portions of the contacts 114 are embedded within the substrate 102 in the memory attach regions 110. To illustrate, the contacts 114 may include metal pads or traces that are disposed on the first surface 106, or at least partially embedded within the substrate 102 (e.g., the substrate 102 may be an ETS), and at least a portion of each pad may be exposed to enable later attachment of multiple memory dies to the contacts 114.

In some implementations, the contacts 114 are configured or arranged to be able to receive multiple types of memory dies that comply with a common memory access protocol. For example, the contacts 114 may be arranged in a layout that matches a pad or interconnect layout of memory dies made by multiple different manufactures, and that optionally have different operating characteristics such as power consumption, read or write speeds, storage capacity, or the like. In some implementations, one or more sets of the contacts 114 are arranged according to a Joint Electron Device Engineering Council (JEDEC) Solid State Technology Association specification for double data rate (DDR) dynamic random access memory (DRAM) interconnection, such that the one or more sets of the contacts 114 are configured to receive JEDEC-compliant DDR DRAMs. In some other implementations, sets of the contacts 114 may be arranged according to other memory access protocols, such as a universal flash storage (UFS) protocol or another protocol.

The conductors 116 electrically couple the contacts 112 to the contacts 114 (e.g., the multiple sets of the contacts 114). For example, the conductors 116 may include traces, vias, metal lines, or a combination thereof, that provide conductive pathways (e.g., electrical connections) between the contacts 112 and the contacts 114. Such conductive pathways may enable the routing of various signals between dies coupled to the contacts 112 and the contacts 114. For example, the conductors 116 may route data signals (e.g., memory access signals) between the die 104 and the memory dies that are eventually attached to the contacts 114. Additionally, or alternatively, the conductors 116 may electrically couple the contacts 112, the contacts 114, or both, to one or more other signal sources. As a non-limiting example, some of the conductors 116 may be configured to route power or ground to the die 104 (e.g., through the contacts 112) or to the contacts 114 for routing to attached memory dies, once the memory dies are attached.

The substrate 102 defines the memory attach regions (e.g., multiple empty memory attach regions in the example shown in FIGS. 1A-B) that are configured to receive multiple memory dies at a later time (e.g., such as when a user or customer selects particular memory dies to attach to the package 100). In the example shown in FIG. 1B, the substrate 102 defines a first memory attach region 110A, a second memory attach region 110B, and a third memory attach region 110C. This example is illustrative, and in other examples, the substrate 102 may define fewer than three or more than three memory attach regions 110. The sets of contacts 114 may be located in the memory attach regions 110. For example, contacts 114A may be located within the first memory attach region 110A, contacts 114B may be located within the second memory attach region 110B, and contacts 114C may be located within the third memory attach region 110C. The memory attach regions 110 may be located “outside of” the die 104, such as between the die 104 and one or more respective edges of the substrate 102. In some implementations, the memory attach regions are each located along (or adjacent or nearby to) at least one edge of the substrate 102. In the example shown in FIG. 1B, the first memory attach region 110A is located along a first edge 122 of the substrate 102, the second memory attach region 110B is located along the first edge 122 and a second edge 124 of the substrate 102, and the third memory attach region 110C is located along the second edge 124. The arrangement and location of the memory attach regions 110 in FIG. 1B is illustrative, and in other examples, one or more of the memory attach regions 110 may be located along other edges of the substrate 102, such as along a third edge 126 or along a fourth edge 128.

The die 104 is electrically coupled to the contacts 112 and includes one or more processors. Although a single die 104 is illustrated in FIGS. 1A-B, in other examples, the die 104 may include or correspond to multiple dies, each of which include respective processor circuitry. The die 104 can include integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate. The die 104 may include or correspond to particular IC devices that can be arranged and interconnected as a 2D IC device, a 2.5D IC device, or a 3D IC device. In some implementations, the die 104 includes one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the die 104.

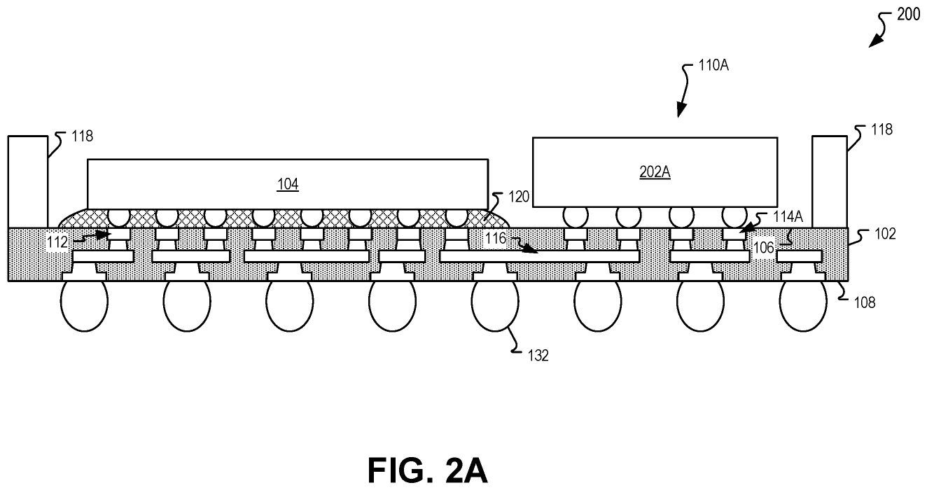

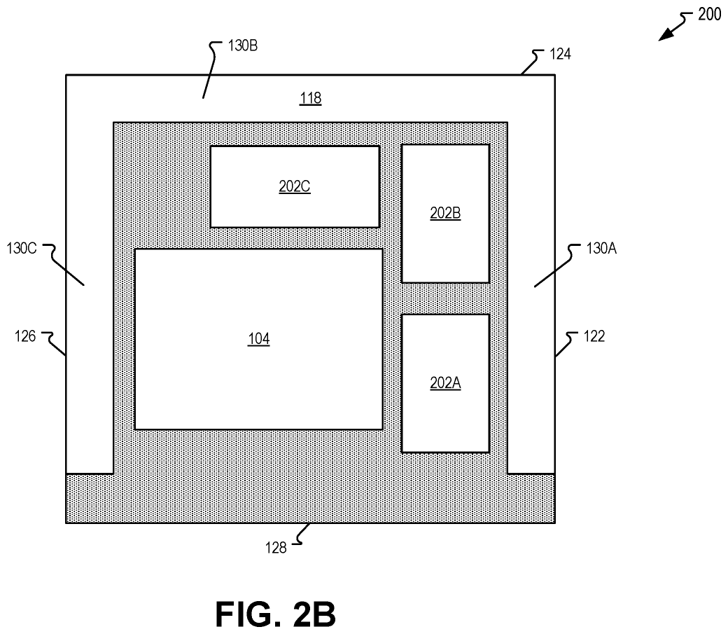

In particular implementations, the die 104 includes one or multiple processors, one or multiple processor cores, or one or more instances of processor circuitry that are interconnected to operate as a processing system, such as an SoC. In implementations in which the die 104 includes or corresponds to an SoC, the die 104 (or processor circuitry thereof) may be an IC that includes some or all of the components of a computer system, such as an on-chip CPU, input/output (I/O) interfaces, memory interfaces, and in some implementations, one or more modems or graphic processing units (GPUs). The SoC may be configured to communicate with one or more memories that correspond to memory dies to be attached to the empty memory attach regions 110, as further described herein with reference to FIGS. 2A-B. Additionally, or alternatively, the die 104 may include or correspond to multiple chiplets that are respectively configured to operate as processors or processor cores and that, when interconnected, operate as an SoC.

The package 100 also includes an underfill material 120 that is disposed between the die 104 and the substrate 102. For example, the underfill material 120 may include polymer or polymerizing compound, such as an epoxy resin, that is deposited between the die 104 and the substrate 102 to provide mechanical support to the die 104 and mitigate stress caused by thermal expansion mismatches. Because the memory attach regions 110 are empty at the time of fabrication of the package 100 (e.g., because no memory dies are attached to the contacts 114), the underfill material 120 is not deposited in the memory attach regions 110. Additionally, the package 100 includes interconnects 132 (e.g., a set of interconnects) coupled to the second surface 108 (e.g., the bottom surface) of the substrate 102. The interconnects 132 may include solder balls, solder bumps, other conductive structures, or the like and may form a ball-grid array (BGA) to provide electrical interconnection between components of the package 100 and one or more external components. For example, the interconnects 132 may be configured to be coupled to a printed circuit board (PCB) or another package (e.g., another integrated package device) to enable the package 100 to be included in a device or system. As used herein, an “external component” refers to a component that is not included in the package 100 or configured to be received by the package 100, such as the multiple memory dies in the memory attach regions 110.

The stiffener structure 118 is optionally coupled to the substrate 102 to assist in maintaining a shape of the substrate 102. For example, the stiffener structure 118 may be configured to resist warpage of the substrate 102 based on mechanical properties of memory dies without the underfill material 120 between the memory dies and the substrate 102, as further described with reference to FIGS. 2A-B. The stiffener structure 118 may be disposed over or along one or more edges of the substrate 102 based on locations of the memory attach regions 110. For example, the stiffener structure 118 may be disposed along edges that are adjacent to or near the memory attach regions 110. Stated another way, one or more of the memory attach regions 110 may be located between the die 104 and the stiffener structure 118, which may cause the stiffener structure 118 to prevent or resist mechanical warpage of the substrate 102 in or near the memory attach regions 110.

The stiffener structure 118 may include one or more walls 130 that are disposed along at least one edge of the substrate 102, such that the wall(s) 130 of the stiffener structure 118 are between at least some of the memory attach regions 110 and respective edges of the substrate 102. In a particular implementation as shown in FIG. 1B, the stiffener structure 118 includes a first wall 130A along the first edge 122, a second wall 130B along the second edge 124, and a third wall 130C along the third edge 126. In this implementation, an end (e.g., a bottom end in FIG. 1B) of the first wall 130A and an end (e.g., a bottom end in FIG. 1B) of the third wall 130C are separated by the fourth edge 128. Stated another way, the stiffener structure 118 does not include a fourth wall along the fourth edge 128. One or more of the memory attach regions 110 may be located between the die 104 and the walls 130 of the stiffener structure 118. For example, the first memory attach region 110A may be located between the die 104 and the first wall 130A, the second memory attach region 110B may be located at least partially between the die 104 and the first wall 130A as well as at least partially between the die 104 and the second wall 130B, and the third memory attach region 110C may be located between the die 104 and the second wall 130B.

In implementations in which the stiffener structure 118 includes three walls 130, the three walls 130 may be disposed along the edges of the substrate 102 that provide the most resistance to warpage to nearby ones of the memory attach regions 110. Although in the example shown in FIG. 1B the walls 130 extend along the edges 122-126, in other examples, the stiffener structure 118 may be arranged such that the walls 130 extend along any three of the four edges 122-128, based on locations of the memory attach regions 110.

Although the package 100 depicted in FIGS. 1A-B includes the stiffener structure 118 having three walls 130, in other implementations, the stiffener structure 118 may have fewer than three walls 130 or more than three walls 130. Referring to FIG. 1C, a package 140 includes the substrate 102 that defines the memory attach regions 110, the die 104, the underfill material 120 (not shown in FIG. 1C), and the stiffener structure 118, similar to the package 100. However, the stiffener structure 118 of the package 140 includes four walls instead of three walls. To illustrate, the stiffener structure 118 includes the first wall 130A, the second wall 130B, the third wall 130C, and a fourth wall 140D. The first wall 130A may extend along the first edge 122 of the substrate 102, the second wall 130B may extend along the second edge 124 of the substrate 102, the third wall 130C may extend along the third edge 126 of the substrate 102, and the fourth wall 130D may extend along the fourth edge 128 of the substrate 102. In this example, the stiffener structure 118 may be referred to as a stiffener ring that extends along all the edges 122-128 of the substrate 102.

Referring to FIG. 1D, a package 150 includes the substrate 102 that defines the memory attach regions 110, the die 104, the underfill material 120 (not shown in FIG. 1D), and the stiffener structure 118, similar to the package 100. However, the stiffener structure 118 of the package 150 includes two walls instead of three walls. To illustrate, the stiffener structure 118 includes the first wall 130A and the second wall 130B. The first wall 130A may extend along the first edge 122 of the substrate 102 and the second wall 130B may extend along the second edge 124 of the substrate 102. In this example, the walls 130 extend along the edges 122-124 due to memory attach regions 110 also being located along the edges 122-124, such that the stiffener structure 118 is closest to the memory attach regions 110 by extending along the two edges 122-124. In other examples, the stiffener structure 118 may extend along any two of the edges 122-128, based on locations of the memory attach regions 110. By including two walls 130A-B (instead of three walls) in the stiffener structure 118, an overall size of the package 150 may be smaller than an overall size of the package 100.

Referring to FIG. 1E, a package 160 includes the substrate 102 that defines the memory attach regions 110, the die 104, the underfill material 120 (not shown in FIG. 1E), and the stiffener structure 118, similar to the package 100. However, the stiffener structure 118 of the package 160 includes one wall (e.g., a single wall) instead of three walls. To illustrate, the stiffener structure 118 includes the first wall 130A. The first wall 130A may extend along the first edge 122 of the substrate 102. In this example, the first wall 130A extends along the first edge 122 due to a substantial length of the memory attach regions 110 also being located along the first edge 122, such that the stiffener structure 118 is closest to a large portion of the memory attach regions 110 by extending along the first edge 122. In other examples, the stiffener structure 118 may extend along any one of the edges 122-128, based on locations of the memory attach regions 110. By including one wall 130A (instead of three walls or two walls) in the stiffener structure 118, an overall size of the package 160 may be smaller than the overall sizes of the package 100 and the package 150.

FIGS. 1F-G depict a package 170 that includes the substrate 102 that defines the memory attach regions 110, the die 104, and the underfill material 120. However, unlike the packages 100, 150, and 160, the package 170 omits the stiffener structure 118. In such implementations, the memory attach regions 110 surround the die 104 on the substrate 102 but are not between the die 104 and the stiffener structure 118. Instead, each of the memory attach regions 110 may be located between the die 104 and one or more of the edges 122-128. For example, as shown in FIG. 1G, the first memory attach region 110A is located between the die 104 and the first edge 122, the second memory attach region 110B is located at least partially between the die 104 and the first edge 122 and at least partially between the die 104 and the second edge 124, and the third memory attach region 110C is located between the die 104 and the second edge 124.

In some implementations in which the stiffener structure 118 is omitted, a respective package may include other structure(s), such as a lid structure to cover components that are part of the package when it is received by the user to attach the multiple memory dies. FIG. 1H depicts a package 180 that includes the substrate 102 that defines the memory attach regions 110, the die 104, and the underfill material 120, and that does not include the stiffener structure 118, similar to the package 170 of FIGS. 1F-G. Unlike the package 170, the package 180 includes a lid structure 134 that is coupled to the substrate 102 and at least partially covers the die 104. The lid structure 134 may include one or more metals or metal alloys, or other materials, that enable the lid structure 134 to be substantially rigid, or partially rigid and partially flexible, to provide cover to the die 104 and prevent, or reduce the likelihood, that the die 104 is bumped or damaged, including during attachment of memory dies to the memory attach regions 110. Although illustrated in FIG. 1H as covering an entirety of the die 104, in other examples, the lid structure 134 may only cover a portion of the die 104.

It should be understood that the packages 100, 140, 150 160, 170, 180, or a combination thereof, may include additional components, other components, fewer components, or a combination thereof, to support the functionality described herein. As non-limiting examples, the packages 100, 140, 150, 160, 170, 180, or a combination thereof, may include additional IC devices, additional layers, additional dies, additional packages, additional interconnects, additional structures, other components, different components, or a combination thereof, to support the functionality and technical advantages disclosed herein.

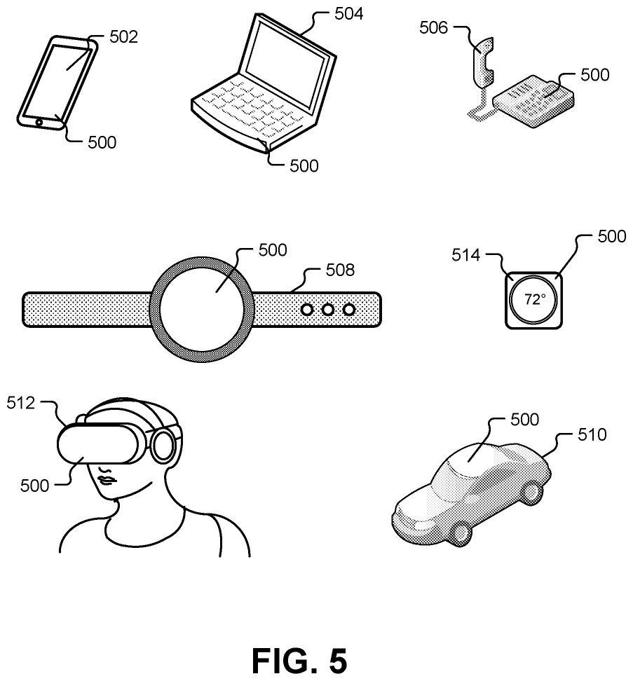

Any of the packages 100, 140, 150, 160, 170, or 180 may be included in or integrated within a mobile device, a hand-held personal communication system (PCS) unit, a portable data unit, a global positioning system (GPS) enabled device, a navigation device, a set top box, a music player, a video player, an entertainment unit, a virtual reality (VR) device, an augmented reality (AR) device, an extended reality (XR) device, a fixed location data unit, a communications device, a smartphone, a tablet computer, a computer, a wearable device, an Internet of things (IoT) device, a server, a router, a vehicle, or a combination thereof, as described in more detail below with reference to FIG. 5. While FIGS. 1A-H illustrate example packages that include the die 104 and the memory attach regions 110 in side-by-side arrangements, in other examples, one or more additional integrated devices, packages, or some combination thereof can be present in a stacked integrated circuit without departing from the scope of the subject disclosure. Further, the packages 100, 140, 150, 160, 170, or 180 can be integrated with or included within a wide variety of other devices. For example, a device that includes any of the packages 100, 140, 150, 160, 170, or 180 disclosed herein can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, a power management processor, and/or combinations thereof. In such devices, the die 104 and memory dies that are attached to the memory die regions 110 can operate as a SiP that can include any of these components (or a combination of these components) that includes active circuitry.

In a particular implementation, any of the packages 100, 140, 150, 160, 170, or 180 include one or more dies (e.g., the die 104) that include one or more processors. In this implementation, any of the packages 100, 140, 150, 160, 170, or 180 also include a substrate (e.g., the substrate 102) that defines multiple empty memory attach regions (e.g., the memory attach regions 110). The substrate includes a first set of contacts (e.g., the contacts 112) electrically coupled to the one or more dies. The substrate also includes multiple second sets of contacts (e.g., the contacts 114) within the multiple empty memory attach regions. At least a portion of each of the multiple second sets of contacts is exposed along an upper surface (e.g., the first surface 106) of the substrate. The multiple second sets of contacts are configured to be electrically coupled to multiple memory dies. The substrate also includes one or more conductors (e.g., the conductors 116) that electrically couple the first set of contacts to the multiple second sets of contacts.

The packages 100, 140, 150, 160, 170, and/or 180 thus provide more flexible SiPs that can be individually designed, through the selection of particular memory dies to be attached, than other SiPs that are manufactured and sold with memory dies already attached. For example, because the contacts 114 can be configured to receive various types of memory dies, such as memory dies by different manufacturers or that have different storage capacities, a user of the packages 100, 140, 150, 160, 170, and/or 180 can select memory dies to attach to the packages 100, 140, 150, 160, 170, and/or 180 to match particular operating criteria, instead of being limited by the operating characteristics of pre-attached memory dies. Additionally, the location of the memory attach regions 110 may be designed to be close to the die 104 to improve signal quality between the die 104 and the memory dies as well as to reduce the overall form factor size of the packages 100, 140, 150, 160, 170, and/or 180, as compared to other SiPs that come with pre-installed memory dies and the underfill material 120 underneath the memory dies, as well as compared to memory dies that include a large number of memory dies to support target operating criteria which may be more stringent than desired for many users. This may reduce cost and complexity of fabricating the packages 100, 140, 150, 160, 170, and/or 180.

FIGS. 2A-B illustrate an example of a package 200 that includes one or more processor dies and multiple later-attached memory dies, such as memory dies that are attached by a user or a customer of a manufacturer associated with one or more of the packages 100, 140, 150, 160, 170, or 180. FIG. 2A illustrates a cross-sectional profile view of the package 200, and FIG. 2B illustrates a top view of the package 200. The package 200 of FIGS. 2A-B includes many of the same components and features as are described above with reference to the package 100 of FIGS. 1A-B, including the stiffener structure 118 that includes three walls (e.g., a 3-sided stiffener structure). Such components and features are physically and operationally the same as described above with reference to FIGS. 1A-B and are labeled in FIGS. 2A-B using the same reference numbers. In some implementations, the package 200 includes all of the same features and components as the package 100 of FIGS. 1A-B; however, in some other implementations, the package 200 may include the components of the package 140 of FIG. 1C, the package 150 of FIG. 1D, the package 160 of FIG. 1E, the package 170 of FIGS. 1F-G, or the package 180 of FIG. 1H.

In the example shown in FIGS. 2A-B, the package 200 includes the substrate 102, the die 104 electrically coupled to the first surface 106 of the substrate 102, the stiffener structure 118 coupled to the first surface 106 of the substrate 102, and the interconnects 132 coupled to the second surface 108 of the substrate 102, similar to as described above with reference to FIGS. 1A-B. The package 200 also includes multiple memory dies 202 that are electrically coupled to the contacts 114. For example, the memory dies 202 may be disposed over the first surface 106 of the substrate 102 in the memory attach regions 110 and electrically coupled to the exposed portions of the contacts 114, similar to as described above for the die 104 and the contacts 112. To illustrate, a first memory die 202A may be coupled to the contacts 114A in the first memory attach region 110A, a second memory die 202B may be coupled to the contacts 114B in the second memory attach region 110B, and a third memory die 202C may be coupled to the contacts 114C in the third memory attach region 110C. Inclusion of the memory dies 202 in the package 200 and interconnection of the memory dies 202 with the die 104 may form an SiP (e.g., the package 200).

The memory dies 202 that are attached to the package 200 may be selected by a user or consumer after fabrication and distribution of the package 100 of FIGS. 1A-B. Accordingly, the memory dies 202 may be the same type of memory dies or one or more of the memory dies 202 may be a different type of memory die than others of the memory dies 202. As non-limiting examples, if the package 200 is to be used in a mobile communication device, the memory dies 202 may include one or more low power DDR4 (LPDDR4), one or more LPDDR5 dies, one or more LPDDR5X dies, other types of DDR dies, or a combination thereof. Additionally, or alternatively, some of the memory dies 202 may support different data widths or different capacities, such as a four bit width, an eight bit width, a sixteen bit width, two gigabytes (GB) storage capacity, four GB storage capacity, eight GB storage capacity, sixteen GB storage capacity, thirty-two GB storage capacity, or the like. As long as the selected memory dies comply with a memory access protocol for which the contacts 114 are configured, the end user can select the number, type, and characteristics of the memory dies 202 to fit their particular design criteria. For example, the contacts 114 may be arranged according to a JEDEC Solid State Technology Association specification for DDR DRAM interconnection, and the memory dies 202 may include on-die contacts or interconnects that are also arranged according to the JEDEC specification for DDR DRAM interconnections.

In some implementations, a pitch associated with contacts of the die 104 (e.g., a first contact pitch) may be smaller than a pitch associated with contacts of the memory dies 202 (e.g., a second contact pitch). As referred to herein, a pitch associated with a set of contacts refers to a distance between two adjacent contacts measured from corresponding points of the two adjacent contacts, such as the centers of the respective contacts. In such implementations, the conductors 116 may form conductive paths from the contacts 112, which have a first pitch, to the contacts 114, which have a second pitch that is different than the first pitch. The first pitch may be associated with one or more specifications for processors or chiplets, and the second pitch may be associated with one or more specifications for memory access, such as the above-mentioned JEDEC specification.

As shown in FIG. 2A, the package 200 includes the underfill material 120 that is disposed between the die 104 and the substrate 102. It is noted that the underfill material 120 is not disposed between the memory dies 202 and the substrate 102, as the underfilling process occurs before the package 100 is distributed, and thus before the memory dies 202 are attached to form the package 200. By omitting the underfill material 120 in the memory attach regions 110, the memory attach regions 110 can be designed based on the size of the memory dies 202 without including additional area for the underfill material 120, which results in smaller memory attach regions 110 and thus a reduction in the overall size of the package 200 (and the packages 100, 140, 150, 160, 170, and 180). Additionally, reducing the size of the memory attach regions 110 can enable the memory dies 202 to be located closer to the die 104, which reduces the length of signal routing between the die 104 and the memory dies 202, which improves signal quality. Additionally, or alternatively, by omitting the underfill material 120 in the memory attach regions 110, there is no additional material underneath the memory dies 202 to be heated up during a process of coupling the package 200 to a PCB (or other device or package), which can involve heating the package 200 to enable reflow of the interconnects 132. Accordingly, a likelihood of the die interconnects of the memory dies 202 melting during the coupling process is reduced or eliminated.

In some implementations, to compensate for the lack of structural support due to the absence of the underfill material 120 under the memory dies 202, the package 200 includes the stiffener structure 118. The stiffener structure 118 is configured to resist warpage of the substrate 102 based on mechanical properties of the memory dies 202, which do not include the underfill material 120 between the memory dies 202 and the first surface 106 of the substrate 102, which may compensate or offset at least some of the structural support associated with the omitted underfill material for the memory dies 202.

In implementations that include the stiffener structure 118, one or more of the memory dies 202 are disposed on the first surface 106 of the substrate 102 between the die 104 and the stiffener structure 118. For example, as shown in FIG. 2B, the first memory die 202A may be located between the die 104 and the first wall 130A, the second memory die 202B may be located at least partially between the die 104 and the first wall 130A as well as at least partially between the die 104 and the second wall 130B, and the third memory die 202C may be located between the die 104 and the second wall 130B. In such examples, the first memory die 202A and the second memory die 202B are located along the first edge 122 and the third memory die 202C is located along the second edge 124.

In implementations in which the stiffener structure 118 includes three walls 130, the three walls 130 may be disposed along the edges of the substrate 102 that provide the most resistance to warpage due to the nearby memory dies 202. Although in the example shown in FIG. 2B the walls 130 extend along the edges 122-126, in other examples, the stiffener structure 118 may be arranged such that the walls 130 extend along any three of the four edges 122-128, based on locations of the memory dies 202. It is noted that, if the underfill material 120 were deposited in the memory attach regions 110, the stiffener structure 118 is typically four-sided and surrounds the entirety of the substrate 102 due to the mechanical properties of the underfill material 120. However, because the underfill material 120 is omitted from the memory attach regions 110, the stiffener structure 118 may be a “u-shape” (as shown in FIG. 2B) that includes three walls, or optionally include more walls (as shown in FIG. 1C) or fewer walls (as shown in FIGS. 1D and 1E) while still providing the resistance to warpage described above. Reducing the number of walls of the stiffener structure 118 can reduce the overall size of the package 200 (or the packages 100, 140, 150, and 160).

Although the package 200 depicted in FIGS. 2A-B includes the stiffener structure 118 having three walls 130, in other implementations, the stiffener structure 118 may have more than three walls 130, such as if the memory dies 202 are attached to the package 140 of FIG. 1C, or fewer than three walls 130, such as if the memory dies 202 are attached to the package 150 of FIG. 1D or the package 160 of FIG. 1E, instead of the package 100 of FIGS. 1A-B. Alternatively, the stiffener structure 118 may be omitted, such as if the memory dies 202 are attached to the package 170 of FIGS. 1F-G or the package 180 of FIG. 1H. In some such implementations, the package 200 may include the lid structure 134, such as if the memory dies 202 are attached to the package 180 of FIG. 1H.

It should be understood that the package 200 may include additional components, other components, fewer components, or a combination thereof, to support the functionality described herein. As non-limiting examples, the package 200 may include additional IC devices, additional layers, additional dies, additional packages, additional interconnects, additional structures, other components, different components, or a combination thereof, to support the functionality and technical advantages disclosed herein.

The package 200 may be included in or integrated within a mobile device, a hand-held PCS unit, a portable data unit, a GPS enabled device, a navigation device, a set top box, a music player, a video player, an entertainment unit, a VR device, an AR device, an XR device, a fixed location data unit, a communications device, a smartphone, a tablet computer, a computer, a wearable device, an IoT device, a server, a router, a vehicle, or a combination thereof, as described in more detail below with reference to FIG. 5. While FIGS. 2A-B illustrate the example package 200 that includes the die 104 and the memory dies 202 in a side-by-side arrangement, in other examples, one or more additional integrated devices, packages, or some combination thereof can be present in a stacked integrated circuit without departing from the scope of the subject disclosure. Further, the package 200 of FIGS. 2A-B can be integrated with or included within a wide variety of other devices. For example, a device that includes the package 200 disclosed herein can include components such as a PMIC, an application processor, a modem, an RF device, a passive device, a filter, a capacitor, an inductor, a transmitter, a receiver, a GaAs-based integrated device, a SAW filter, a BAW filter, a LED integrated device, a Si-based integrated device, a SiC-based integrated device, a memory, a power management processor, and/or combinations thereof. In such devices, the die 104 and the memory dies 202 can operate as a SiP that can include any of these components (or a combination of these components) that includes active circuitry.

In a particular implementation, the package 200 includes a substrate (e.g., the substrate 102). The substrate includes a first set of contacts (e.g., the contacts 112), multiple second sets of contacts (e.g., the contacts 114), and one or more conductors (e.g., the conductors 116) that electrically couple the first set of contacts to the multiple second sets of contacts. The package 200 also includes one or more dies (e.g., the die 104) electrically coupled to the first set of contacts. The one or more dies includes one or more processors. The package 200 also includes multiple memory dies (e.g., the memory dies 202) electrically coupled to the multiple second sets of contacts. An underfill material (e.g., the underfill material 120) is disposed between the one or more dies and the substrate and not between the multiple memory dies and the substrate.

The package 200 provides the same improved flexibility described above with reference to the packages 100, 140, 150, 160, 170, and/or 180, through the selection of particular memory dies as the memory dies 202. For example, because the contacts 114 can be configured to receive various types of memory dies, such as memory dies by different manufacturers or that have different storage capacities, a user of the package 200 can select the memory dies 202 that best match particular operating criteria, instead of being limited by the operating characteristics of pre-attached memory dies. Additionally, the location of the memory dies 202 may be designed to be close to the die 104 to improve signal quality between the die 104 and the memory dies 202 as well as to reduce the overall form factor size of the package 200. In implementations that include the stiffener structure 118, the stiffener structure 118 may reduce warpage of the substrate 102 during the process of attaching the memory dies 202, due to the presence of the memory dies 202 during the life of the package 200, or both, which can decrease a likelihood of damage to the die 104 or the package 200 during the process of attaching the memory dies 202 or which can increase the operational lifespan of the package 200.

### Exemplary Sequence for Fabricating a Package Including Processor Die(s) and Configured to Receive Multiple Memory Dies

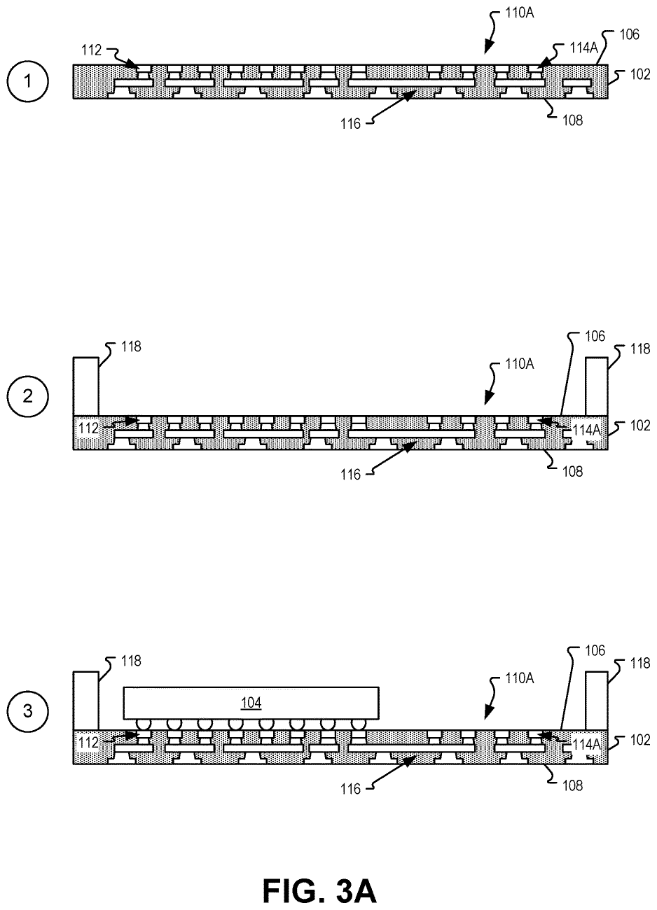

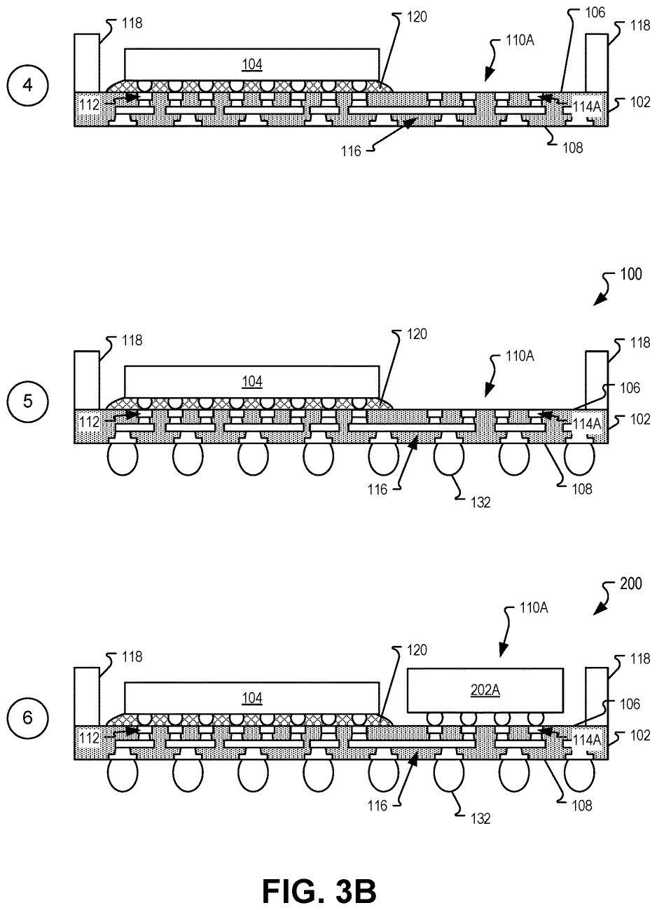

In some implementations, fabricating a device that includes a package including one or more processors and that is configured to receive multiple memory dies (e.g., any of the packages 100, 140, 150, 160, 170, 180, or 200) includes several processes. FIGS. 3A-B illustrate an exemplary sequence for fabricating or providing a package that includes one or more processors and that is configured to receive multiple memory dies, as described with reference to any of FIGS. 1A-H and 2A-B. In some implementations, the sequence of FIGS. 3A-B may be used to provide (e.g., during fabrication of) the package 200 of FIGS. 2A-B. Other implementations described herein may be used to form one or more of the package 100 of FIGS. 1A-B, the package 140 of FIG. 1C, the package 150 of FIG. 1D, the package 160 of FIG. 1E, the package 170 of FIGS. 1F-G, or the package 180 of FIG. 1H.

It should be noted that the sequence of FIGS. 3A-B may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 3A-B. Each of the various stages of the sequence illustrated in FIGS. 3A-B shows a single integrated device package (e.g., a single SiP) being formed. In other implementations, a plurality of integrated device packages can be formed concurrently.

Stage 1 of FIG. 3A illustrates a state after providing the substrate 102. For example, as part of Stage 1, the substrate 102 may be formed or acquired for use in forming a package (e.g., an integrated device package). Formation of the substrate 102 may include forming a metal-prepreg stack or redistribution layers. The substrate 102 may define the attach regions 110 (e.g., multiple empty memory attach regions) and include the contacts 112 (e.g., a first set of contacts), the contacts 114 (e.g., multiple second sets of contacts) within the memory attach regions 110, and the conductors 116 (e.g., one or more conductors) that electrically couple the contacts 112 to the contacts 114. At least a portion of each of the contacts 114 is exposed along the first surface 106 of the substrate 102, and the contacts 114 are configured to be electrically coupled to multiple memory dies, as described above with reference to FIGS. 1A-B. For example, each set of the contacts 114 is located within a respective one of the memory attach regions 110 and have at least a portion of the contacts 114 exposed to enable electrical coupling to memory dies. The contacts 114 may be disposed on the first surface 106 of the substrate 102 or at least partially embedded within the substrate 102.

Stage 2 illustrates a state after coupling the stiffener structure 118 to the substrate 102. For example, as part of Stage 2, the stiffener structure 118 may be coupled along one or more edges (e.g., the edges 122-126) of the substrate 102. In some implementations, the memory attach regions 110 are located along at least one edge of the substrate 102, and coupling the stiffener structure 118 to the substrate 102 includes coupling the stiffener structure 118 along the same edge(s), as described above with reference to FIGS. 1B-E, and 2B. Additionally, or alternatively, one or more of the memory attach regions 110 are located between the die 104 and the stiffener structure 118, as described above with reference to FIGS. 1B-E.

Stage 3 illustrates a state after electrically coupling one or more dies (e.g., the die 104) to the contacts 112. For example, as part of Stage 3, the die 104 may be attached to the contacts 112 (e.g., to the first surface 106 of the substrate 102), such as using flip chip die attachment operations. The die 104 may include or correspond to one or more processors and, in some implementations, the die 104 may be an SoC. Although illustrated as a single die 104 in FIG. 3A, in some other implementations, the die 104 includes multiple dies that each include respective processor circuitry, such as multiple chiplets. Although FIG. 3A depicts the operations of Stage 3 being performed after the operations of Stage 2, in some other implementations, the die 104 may be electrically coupled to the substrate 102 before the stiffener structure 118 is coupled to the substrate 102.

Stage 4 of FIG. 3B illustrates a state after depositing the underfill material 120 between the die 104 and the substrate 102. For example, as part of Stage 4, the underfill material 120, such as an epoxy or other polymer, may be deposited between the die 104 and the substrate 102 to provide mechanical support and other advantageous properties to the die 104, the substrate 102, or both. It is noted that Stage 4 does not include depositing the underfill material 120 in the memory attach regions 110, which results in the memory dies that are eventually coupled to these regions lacking the underfill material 120 underneath.

Stage 5 illustrates a state after coupling the interconnects 132 (e.g., a set of interconnects) to the substrate 102. For example, as part of Stage 5, BGA balls, solder balls, or other conductive structures may be electrically coupled to contacts on, or embedded within, the second surface 108 of the substrate 102 to form the interconnects 132 that are configured to facilitate an electrical connection with another device or a PCB once the interconnects 132 are coupled to such a device or PCB. In some implementations, Stages 1-5 can be performed at a strip level or a panel level. For example, the substrate 102 illustrated in Stages 1-5 can correspond to a portion of a strip of package substrates or a panel of package substrates. In such implementations, Stage 5 illustrates a state after package singulation, such as by cutting the strip or panel of package substrates to form an individual integrated device package, as depicted in Stage 6. In some implementations, formation of the package 100 (e.g., a package including one or more processor dies and that is configured to receive multiple memory dies) is complete after Stage 5 of FIG. 3B.

Stage 6 illustrates a state after electrically coupling the memory dies 202 to the contacts 114. For example, as part of Stage 6, the memory dies 202 may be disposed over the memory attach regions 110, and each of the memory dies 202 may be electrically coupled to a respective set of the contacts 114. Such a process omits depositing the underfill material 120 within the memory attach regions 110 (e.g., between the memory dies 202 and the first surface 106 of the substrate 102). As described above, the memory dies 202 may include one or more memory dies that have different manufactures or operational characteristics than others of the memory dies 202, such as data width, storage capacity, or the like. In some implementations, the contacts 114 and contacts or interconnects of the memory dies 202 are arranged in compliance with a JEDEC specification for DDR DRAM interconnections.

Formation of the package 200 (e.g., a package including one or more processor dies and multiple memory dies) is complete after Stage 6 of FIG. 3B. However, in some implementations, one or more of the operations described above with reference to FIGS. 3A-B may be omitted or modified to form the package 100 of FIGS. 1A-B, the package 140 of FIG. 1C, the package 150 of FIG. 1D, the package 160 of FIG. 1E, the package 170 of FIGS. 1F-G, or the package 180 of FIG. 1H. For example, Stage 6 of FIG. 3B may be omitted (e.g., attachment of the memory dies 202 may be omitted) to form the package 100 of FIGS. 1A-B, the stiffener structure may include more than three walls to form the package 140 of FIG. 1C, or the stiffener structure 118 may include fewer than three walls, such as two walls or a single wall, to form the package 150 of FIG. 1D or the package 160 of FIG. 1E, respectively. As another example, Stage 2 of FIG. 3A may be omitted (e.g., the stiffener structure 118 may be omitted) to form the package 170 of FIGS. 1F-G. As another example, Stage 2 of FIG. 3A may be omitted (e.g., the stiffener structure 118 may be omitted) and the sequence may include coupling the lid structure 134 to the substrate 102 to at least partially cover the die 104 to form the package 180 of FIG. 1H.

### Exemplary Flow Diagram of a Method for Fabricating a Package Including Processor Die(s) and Configured to Receive Multiple Memory Dies

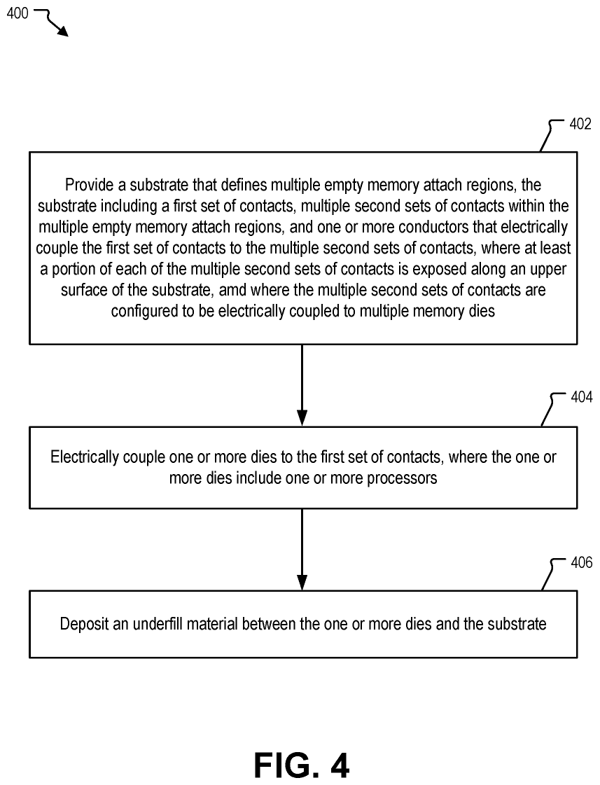

In some implementations, fabricating a package including one or more processor dies and that is configured to receive multiple memory dies includes several processes. FIG. 4 illustrates an exemplary flow diagram of a method 400 of fabricating an illustrative package that includes one or more processor dies and that is configured to receive multiple memory dies. In a particular aspect, one or more operations of the method 400 are performed by one or more processors of a fabrication system. In some implementations, operations of the method 400 may be stored as instructions by a non-transitory computer-readable storage medium, and the instructions may be executable by at least one processor to cause the at least one processor to perform operations of the method 400. In some implementations, the method 400 of FIG. 4 may be used to provide or fabricate any of the package 100 of FIGS. 1A-B, the package 140 of FIG. 1C, the package 150 of FIG. 1D, the package 160 of FIG. 1E, the package 170 of FIGS. 1F-G, the package 180 of FIG. 1H, or the package 200 of FIGS. 2A-B.

It should be noted that the method 400 of FIG. 4 may combine one or more processes in order to simplify and/or clarify the method for providing or fabricating package. In some implementations, the order of the processes may be changed or modified.

The method 400 includes providing a substrate that defines multiple empty memory attach regions, at block 402. For example, Stage 1 of FIG. 3A illustrates and describes examples of providing the substrate 102 that defines the multiple memory attach regions 110. The substrate of the method 400 can include the substrate 102 of FIGS. 1A-3B and the multiple memory attach regions can include the memory attach regions 110 of FIGS. 1A-3B. The substrate of the method 400 may include a first set of contacts, multiple second sets of contacts within the multiple empty memory attach regions, and one or more conductors that electrically couple the first set of contacts to the multiple second sets of contacts. For example, the first set of contacts of the method 400 may include the contacts 112 of FIGS. 1A, 1F, 2A, and 3A-3B, the multiple second sets of contacts of the method 400 may include the contacts 114 of FIGS. 1A-3B, and the one or more conductors of the method 400 may include the conductors 116 of FIGS. 1A, 1F, 2A, and 3A-B. At least a portion of each of the multiple second sets of contacts is exposed along an upper surface of the substrate, and the multiple second sets of contacts are configured to be electrically coupled to multiple memory dies, as described above with reference to FIGS. 1A-H and FIG. 3A. In some implementations, one or more of the multiple second sets of contacts are arranged according to a JEDEC Solid State Technology Association specification for DRAM interconnection.

The method 400 includes electrically coupling one or more dies die to the first set of contacts, at block 404. For example, Stage 3 of FIG. 3A illustrates and describes examples of electrically coupling the die 104 to the substrate 102. The one or more dies include one or more processors. The one or more dies of the method 400 can include the die 104 of FIGS. 1A-3B.

The method 400 includes depositing an underfill material between the one or more dies and the substrate, at block 406. For example, Stage 4 of FIG. 3B illustrates and describes examples of depositing the underfill material 120. The underfill material of the method 400 can include the underfill material 120 of FIGS. 1A, 1F, 2A, and 3B.

In some implementations, the method 400 also includes electrically coupling multiple memory dies to the multiple second sets of contacts without depositing the underfill material within the multiple empty memory attach regions. For example, Stage 6 of FIG. 3B illustrates and describes examples of electrically coupling the memory dies 202 to the substrate 102. The multiple memory dies of the method 400 can include the memory dies 202 of FIGS. 2A-B and 3B.

In some implementations, the method 400 also includes coupling a set of interconnects to a second surface of the substrate that is opposite from a first surface of the substrate. In such implementations, the one or more dies are coupled to the first surface of the substrate. For example, Stage 5 of FIG. 3B illustrates and describes examples of coupling the interconnects 132 to the second surface 108 of the substrate 102. The set of interconnects of the method 400 can include the interconnects 132 of FIGS. 1A, 1F, 2A, and 3B.

In some implementations, the method 400 also includes coupling a stiffener structure to the substrate. For example, Stage 2 of FIG. 3A illustrates and describes examples of coupling the stiffener structure 118 to the first surface 106 of the substrate 102. The stiffener structure of the method 400 can include the stiffener structure 118 of FIGS. 1A, 1F, 2A, and 3A-B. The stiffener structure 118 may be configured to resist warpage of the substrate 102 based on mechanical properties of the memory dies 202 without the underfill material 120 between the memory dies 202 and the substrate 102, as further described above. In some such implementations, the multiple empty memory attach regions are located along at least one edge of the substrate and coupling the stiffener structure to the substrate includes coupling the stiffener structure along the at least one edge of the substrate. For example, the stiffener structure 118 may include a plurality of walls, such as three walls that are coupled to the substrate 102 along the edges 122-126, as shown in FIG. 1B, two walls that are coupled to the substrate 102 along the edges 122-124, as shown in FIG. 1D, or one wall that is coupled to the substrate 102 along the first edge 122, as shown in FIG. 1E. Additionally, or alternatively, one or more of the multiple empty memory attach regions 110 are located between the die 104 and the stiffener structure 118, as shown in FIGS. 1B-E.

In other implementations, the stiffener structure 118 is omitted, as shown in FIGS. 1F-G. Additionally, or alternatively, the multiple empty memory attach regions 110 may be located outside of the die 104 (and not between the die 104 and the stiffener structure 118), at least as shown in FIGS. 1F-G. In some implementations in which the stiffener structure is omitted, the method 400 also includes coupling a lid structure to the substrate to at least partially cover the one or more dies. For example, the lid structure of the method 400 may include the lid structure 134 of FIG. 1H.

### Exemplary Electronic Devices

FIG. 5 illustrates various electronic devices that may include or have integrated within any of the packages 100, 140, 150, 160, 170, 180, or 200 (that includes one or more processor dies and that is configured to receive multiple memory dies). For example, a mobile phone device 502, a laptop computer device 504, a fixed location terminal device 506, a wearable device 508, a vehicle 510 (e.g., an automobile or an aerial device), a VR/AR/XR device 512, or an IoT device 514 (e.g., a smart thermostat or another type of IoT device) may include a device 500. The device 500 can include, for example, any of the package 100, the package 140, the package 150, the package 160, the package 170, the package 180, the package 200, and/or any other integrated device package that includes one or more processor dies and that is configured to receive multiple memory dies described herein. The devices 502, 504, 506, 508, 512, and 514 and the vehicle 510 illustrated in FIG. 5 are merely exemplary. Other electronic devices may also feature the device 500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-5 may be rearranged and/or combined into a single component, process, feature or function or embodied in several components, processes, or functions. Additional elements, components, processes, and/or functions may also be added without departing from the disclosure. It should also be noted FIGS. 1A-5 and its corresponding description in the present disclosure is not limited to dies and/or ICs or packages. In some implementations, FIGS. 1A-5 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, an integrated device package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately ‘value X’”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the terms “the plurality of components” may refer to all ten components or only some of the components from the ten components.

In some implementations, an interconnect is an element or component of a device or a package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. A UBM layer may include a thin film metal layer formed between an IC or metal pillars and solder bumps, such as in a flip chip package. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a package includes: one or more dies that include one or more processors; and a substrate that defines multiple empty memory attach regions, where the substrate includes: a first set of contacts electrically coupled to the one or more dies; multiple second sets of contacts within the multiple empty memory attach regions, where at least a portion of each of the multiple second sets of contacts is exposed along an upper surface of the substrate, and where the multiple second sets of contacts are configured to be electrically coupled to multiple memory dies; and one or more conductors that electrically couple the first set of contacts to the multiple second sets of contacts.

Example 2 includes the package of Example 1, where one or more of the multiple second sets of contacts are arranged according to a Joint Electron Device Engineering Council (JEDEC) Solid State Technology Association specification for double data rate (DDR) dynamic random access memory (DRAM) interconnection.

Example 3 includes the package of Example 1 or Example 2, and further includes an underfill material disposed between the one or more dies and the substrate.

Example 4 includes the package of any of Examples 1 to 3, where the multiple empty memory attach regions are located along at least one edge of the substrate.

Example 5 includes the package of any of Examples 1 to 4, and further includes a stiffener structure coupled to the substrate.

Example 6 includes the package of Example 5, where the stiffener structure includes a plurality of walls along at least one edge of the substrate.

Example 7 includes the package of Example 6, where the plurality of walls includes: a first wall along a first edge of the at least one edge of the substrate; a second wall along a second edge of the at least one edge of the substrate; and a third wall along a third edge of the at least one edge of the substrate.

Example 8 includes the package of Example 7, where an end of the first wall and an end of the third wall are separated by a fourth edge of the substrate.

Example 9 includes the package of any of Examples 1 to 4, and further includes a lid structure coupled to the substrate and at least partially covering the one or more dies.

Example 10 includes the package of any of Examples 1 to 9, where the multiple second sets of contacts are exposed on the upper surface of the substrate in the multiple empty memory attach regions.

Example 11 includes the package of any of Examples 1 to 9, where at least portions of the multiple second sets of contacts are embedded within the substrate in the multiple empty memory attach regions.

Example 12 includes the package of any of Examples 1 to 11, where the package is integrated within a mobile device, a hand-held personal communication system (PCS) unit, a portable data unit, a global positioning system (GPS) enabled device, a navigation device, a set top box, a music player, a video player, an entertainment unit, a virtual reality (VR) device, an augmented reality (AR) device, an extended reality (XR) device, a fixed location data unit, a communications device, a smartphone, a tablet computer, a computer, a wearable device, an Internet of things (IoT) device, a server, a router, a vehicle, or a combination thereof.

According to Example 13, a package includes: a substrate including: a first set of contacts; multiple second sets of contacts; and one or more conductors that electrically couple the first set of contacts to the multiple second sets of contacts; one or more dies electrically coupled to the first set of contacts, where the one or more dies include one or more processors; and multiple memory dies electrically coupled to the multiple second sets of contacts, where an underfill material is disposed between the one or more dies and the substrate and not between the multiple memory dies and the substrate.

Example 14 includes the package of Example 13, and further includes a stiffener structure coupled to the substrate.

Example 15 includes the package of Example 14, where the stiffener structure is configured to resist warpage of the substrate based on mechanical properties of the multiple memory dies without the underfill material between the multiple memory dies and the substrate.

Example 16 includes the package of Examples 14 or Example 15, where the one or more dies, the multiple memory dies, and the stiffener structure are coupled to a first surface of the substrate.

Example 17 includes the package of Example 16, and further includes a set of interconnects coupled to a second surface of the substrate that is opposite from the first surface, where the set of interconnects are configured to be coupled to a printed circuit board (PCB) or another package.

Example 18 includes the package of Example 13, and further includes a lid structure coupled to the substrate and at least partially covering the one or more dies.

Example 19 includes the package of any of Examples 13 to 18, where one or more of the multiple second sets of contacts are arranged according to a Joint Electron Device Engineering Council (JEDEC) Solid State Technology Association specification for double data rate (DDR) dynamic random access memory (DRAM) interconnection.

According to Example 20, a method of fabrication includes: providing a substrate that defines multiple empty memory attach regions, the substrate including: a first set of contacts; multiple second sets of contacts within the multiple empty memory attach regions, where at least a portion of each of the multiple second sets of contacts is exposed along an upper surface of the substrate, and where the multiple second sets of contacts are configured to be electrically coupled to multiple memory dies; and one or more conductors that electrically couple the first set of contacts to the multiple second sets of contacts; electrically coupling one or more dies to the first set of contacts, where the one or more dies include one or more processors; and depositing an underfill material between the one or more dies and the substrate.

Example 21 includes the method of Example 20, and further includes electrically coupling multiple memory dies to the multiple second sets of contacts without depositing the underfill material within the multiple empty memory attach regions.

Example 22 includes the method of Example 20 or Example 21, and further includes coupling a set of interconnects to a second surface of the substrate that is opposite from a first surface of the substrate, where the one or more dies is coupled to the first surface of the substrate.

Example 23 includes the method of any of Examples 20 to 22, and further includes coupling a stiffener structure to the substrate.

Example 24 includes the method of Example 23, where: the multiple empty memory attach regions are located along at least one edge of the substrate, and said coupling the stiffener structure to the substrate includes coupling the stiffener structure along the at least one edge of the substrate.

Example 25 includes the method of any of Examples 20 to 22, and further includes coupling a lid structure to the substrate to at least partially cover the one or more dies.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A package comprising:
one or more dies that comprise one or more processors; and
a substrate that defines multiple empty memory attach regions, wherein the substrate includes:
a first set of contacts electrically coupled to the one or more dies;
multiple second sets of contacts within the multiple empty memory attach regions, wherein at least a portion of each of the multiple second sets of contacts is exposed along an upper surface of the substrate, and wherein the multiple second sets of contacts are configured to be electrically coupled to multiple memory dies; and
one or more conductors that electrically couple the first set of contacts to the multiple second sets of contacts.

2. The package of claim 1, wherein one or more of the multiple second sets of contacts are arranged according to a Joint Electron Device Engineering Council (JEDEC) Solid State Technology Association specification for double data rate (DDR) dynamic random access memory (DRAM) interconnection.

3. The package of claim 1, further comprising:
an underfill material disposed between the one or more dies and the substrate.

4. The package of claim 1, wherein the multiple empty memory attach regions are located along at least one edge of the substrate.

5. The package of claim 1, further comprising:
a stiffener structure coupled to the substrate, wherein the stiffener structure includes a plurality of walls along at least one edge of the substrate.

6. The package of claim 5, wherein the plurality of walls includes:
a first wall along a first edge of the at least one edge of the substrate;
a second wall along a second edge of the at least one edge of the substrate; and
a third wall along a third edge of the at least one edge of the substrate, wherein an end of the first wall and an end of the third wall are separated by a fourth edge of the at least one edge of the substrate.

7. The package of claim 1, further comprising:
a lid structure coupled to the substrate and at least partially covering the one or more dies.

8. The package of claim 1, wherein the multiple second sets of contacts are exposed on the upper surface of the substrate in the multiple empty memory attach regions.

9. The package of claim 1, wherein at least portions of the multiple second sets of contacts are embedded within the substrate in the multiple empty memory attach regions.

10. The package of claim 1, wherein the package is integrated within a mobile device, a hand-held personal communication system (PCS) unit, a portable data unit, a global positioning system (GPS) enabled device, a navigation device, a set top box, a music player, a video player, an entertainment unit, a virtual reality (VR) device, an augmented reality (AR) device, an extended reality (XR) device, a fixed location data unit, a communications device, a smartphone, a tablet computer, a computer, a wearable device, an Internet of things (IoT) device, a server, a router, a vehicle, or a combination thereof.

11. A package comprising:
a substrate comprising:
a first set of contacts;
multiple second sets of contacts; and
one or more conductors that electrically couple the first set of contacts to the multiple second sets of contacts;
one or more dies electrically coupled to the first set of contacts, wherein the one or more dies comprise one or more processors; and
multiple memory dies electrically coupled to the multiple second sets of contacts,
wherein an underfill material is disposed between the one or more dies and the substrate and not between the multiple memory dies and the substrate.

12. The package of claim 11, further comprising:
a stiffener structure coupled to the substrate, wherein the stiffener structure is configured to resist warpage of the substrate based on mechanical properties of the multiple memory dies without the underfill material between the multiple memory dies and the substrate.

13. The package of claim 12, wherein the one or more dies, the multiple memory dies, and the stiffener structure are coupled to a first surface of the substrate, and further comprising:
a set of interconnects coupled to a second surface of the substrate that is opposite from the first surface, wherein the set of interconnects are configured to be coupled to a printed circuit board (PCB) or another package.

14. The package of claim 11, further comprising:
a lid structure coupled to the substrate and at least partially covering the one or more dies.

15. The package of claim 11, wherein one or more of the multiple second sets of contacts are arranged according to a Joint Electron Device Engineering Council (JEDEC) Solid State Technology Association specification for double data rate (DDR) dynamic random access memory (DRAM) interconnection.

16. A method of fabrication, the method comprising:
providing a substrate that defines multiple empty memory attach regions, the substrate including:
a first set of contacts;
multiple second sets of contacts within the multiple empty memory attach regions, wherein at least a portion of each of the multiple second sets of contacts is exposed along an upper surface of the substrate, and wherein the multiple second sets of contacts are configured to be electrically coupled to multiple memory dies; and
one or more conductors that electrically couple the first set of contacts to the multiple second sets of contacts;
electrically coupling one or more dies to the first set of contacts, wherein the one or more dies comprise one or more processors; and
depositing an underfill material between the one or more dies and the substrate.

17. The method of claim 16, further comprising:
electrically coupling multiple memory dies to the multiple second sets of contacts without depositing the underfill material within the multiple empty memory attach regions.

18. The method of claim 16, further comprising:
coupling a set of interconnects to a second surface of the substrate that is opposite from a first surface of the substrate, wherein the one or more dies are coupled to the first surface of the substrate.

19. The method of claim 16, wherein the multiple empty memory attach regions are located along at least one edge of the substrate, and further comprising:
coupling a stiffener structure to the substrate along the at least one edge of the substrate.

20. The method of claim 16, further comprising:
coupling a lid structure to the substrate to at least partially cover the one or more dies.
